(19) United States
(12) Patent Application Publication
(10) Pub. No.: US 2026/0068495 A1
(43) Pub. Date: Mar. 5, 2026

(54) DISPLAY DEVICE

(71) Applicant: Magnolia White Corporation, Tokyo (JP)

(72) Inventors: Hideyuki TAKAHASHI, Tokyo (JP); Yasuhito ARUGA, Tokyo (JP)

(73) Assignee: Magnolia White Corporation, Tokyo (JP)

(21) Appl. No.: 19/297,006

(22) Filed: Aug. 12, 2025

(30) Foreign Application Priority Data
Aug. 30, 2024 (JP) 2024-148516

(51) Int. Cl. H10K 59/80; H10K 59/122

(52) U.S. Cl. CPC H10K 59/873; H10K 59/122

(57) ABSTRACT

According to one embodiment, a display device includes a substrate, a first inorganic insulating layer disposed above the substrate over the display area displaying images and the peripheral area surrounding the display area, pads disposed above the first inorganic insulating layer in the peripheral area, a dam disposed above the first inorganic insulating layer and surrounding the display area, and an organic insulating layer continuously formed between the dam and the pads to connect to the dam, and having a first aperture overlapping each of the pads.

### CROSS-REFERENCE TO RELATED APPLICATIONS

This application is based upon and claims the benefit of priority from Japanese Patent Application No. 2024-148516, filed Aug. 30, 2024, the entire contents of which are incorporated herein by reference.

### FIELD

Embodiments described herein relate generally to a display device.

### BACKGROUND

In recent years, display devices in which organic light-emitting diodes (OLEDs) are applied as display elements have been put into practical use. Such display elements comprise a pixel circuit including a thin-film transistor, a lower electrode connected to the pixel circuit, an organic layer covering the lower electrode, and an upper electrode covering the organic layer. The organic layer includes functional layers such as a hole transport layer and an electron transport layer in addition to a light-emitting layer. In such display devices, a technology of suppressing degradation in reliability is required.

### BRIEF DESCRIPTION OF THE DRAWINGS

FIG. 1 is a diagram showing a configuration example of a display device according to the first embodiment.

FIG. 2 is a plan view schematically showing an example of layout of subpixels.

FIG. 3 is a cross-sectional view schematically showing the display device taken along the line III-III in FIG. 2.

FIG. 4 is a plan view showing a configuration example of a mount area of the display device shown in FIG. 1.

FIG. 5 is a plan view showing another configuration example of the mount area of the display device shown in FIG. 1.

FIG. 6 is a cross-sectional view schematically showing the display device taken along the line VI-VI in FIG. 5.

FIG. 7 is a cross-sectional view schematically showing the display device taken along the line VII-VII in FIG. 5.

FIG. 8 is a cross-sectional view schematically showing the display device taken along the line VIII-VIII in FIG. 1.

FIG. 9 is a cross-sectional view schematically showing a display device according to a comparative example.

FIG. 10 is a cross-sectional view schematically showing a display device according to the second embodiment.

FIG. 11 is a cross-sectional view schematically showing the display device according to the second embodiment.

FIG. 12 is a plan view schematically showing a display device according to the third embodiment.

FIG. 13 is a cross-sectional view schematically showing the display device taken along the line XIII-XIII in FIG. 12.

FIG. 14 is a cross-sectional view schematically showing the display device taken along the line XIV-XIV in FIG. 12.

FIG. 15 is a cross-sectional view schematically showing the display device according to the third embodiment.

### DETAILED DESCRIPTION

In general, according to one embodiment, a display device includes a substrate, a first inorganic insulating layer disposed above the substrate over the display area displaying images and the peripheral area surrounding the display area, pads disposed above the first inorganic insulating layer in the peripheral area, a dam disposed above the first inorganic insulating layer and surrounding the display area, and an organic insulating layer continuously formed between the dam and the pads to connect to the dam, and having a first aperture overlapping each of the pads.

With configurations such as described above, it is possible to provide a display device which can suppress the decrease in reliability.

Each of the embodiments will now be described hereinafter with reference to the accompanying drawings. Note that the disclosure is merely an example, and proper changes within the spirit of the invention, which are easily conceivable by a skilled person, are included in the scope of the invention as a matter of course.

In addition, as to the drawings, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction X, a direction along the Y axis is referred to as a second direction Y and a direction along the Z axis is referred to as a third direction Z. Further, viewing the constitutional elements parallel to the Z direction is referred to as plan view.

In the following description, the expression “overlapping” refers not only to cases where other elements overlap the target element from the third direction Z, but also to cases where other elements overlap the target element from the direction opposite to the third direction Z. Further, the expression “overlapping” refers not only to cases where the target elements are in contact with each other, but also to cases where the target elements are spaced apart or where other elements are located between the target elements.

The display device according to each of the embodiments is an organic electroluminescence display device comprising organic light-emitting diodes (OLEDs) as display elements, and may be incorporated into various electronic devices such as televisions, personal computers, in-vehicle devices, tablet terminals, smartphones, mobile phone terminals, and wearable devices.

### First Embodiment

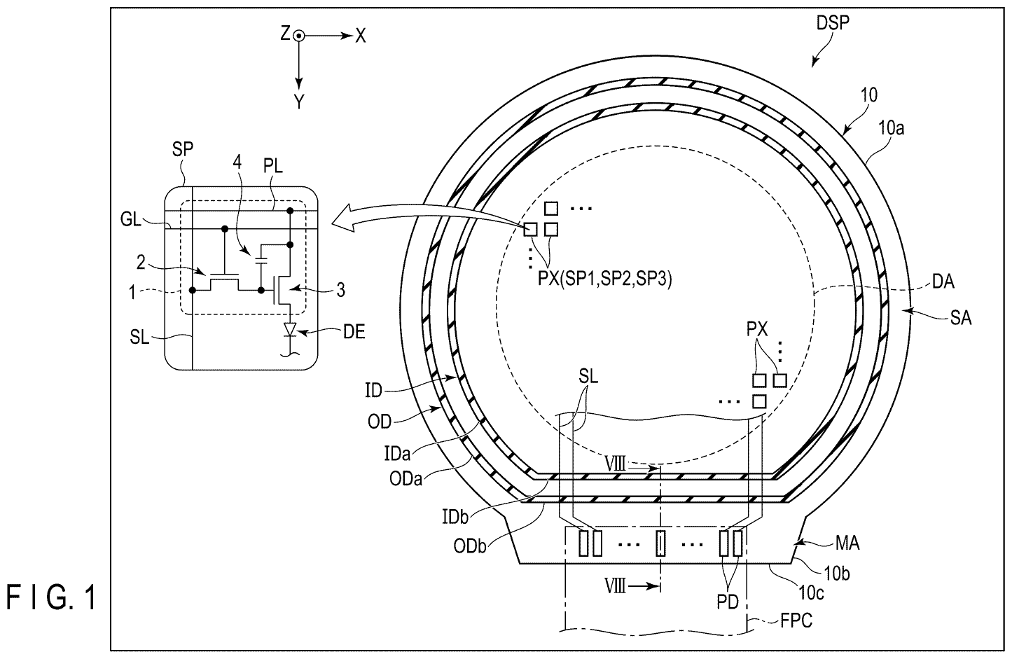

FIG. 1 is a diagram showing a configuration example of a display device DSP according to this embodiment. The display device DSP comprises a substrate 10, a plurality of conductive pads PD, and a flexible printed circuit board FPC connected to the pads PD. The substrate 10 includes a circular main body portion 10a and an extending portion 10b extending from the main body portion 10a in a second direction Y. The extending portion 10b is formed into a trapezoidal shape, the width of which along the first direction X decreases as the location is farther away from the main body portion 10a. The extending portion 10b has a substrate end 10c extending in the first direction X.

Note here that the shape of the substrate 10 in plan view may be some other one such as rectangular, square, or elliptical. The substrate 10 is formed of an insulating material such as glass or plastic.

The display device DSP further comprises a display area DA which displays images and a peripheral area SA surrounding the display area DA. The display area DA overlaps the main body portion 10a in plan view. In this embodiment, the shape of the display area DA in plan view is circular. Note here that the shape of the display area DA in plan view may as well be some other one such as rectangular, square, or elliptical.

The peripheral area SA includes a mount area MA. The mount area MA corresponds to the area which overlaps the extending portion 10b in plan view. The pads PD are provided in the mount area MA. In the example shown in FIG. 1, the pads PD are arranged at intervals along the first direction X. The flexible printed circuit board FPC is connected to the pads PD via an adhesive described below. In addition to the flexible printed circuit board FPC, IC chips and the like may be further mounted on the mount area MA.

The display area DA comprises a plurality of pixels PX arranged in a matrix along the first direction X and the second direction Y. Each of the pixels PX comprises multiple subpixels SP. In one example, the pixels PX each comprise a blue subpixel SP1, a green subpixel SP2, and a red subpixel SP3. Note that apart from the case where there are subpixels of three colors, the pixels PX may contain four or more subpixels in addition to the above pixels of the three colors, which is, for example, white.

The subpixels SP each comprise a pixel circuit 1 and a display element DE driven by the pixel circuit 1. The pixel circuit 1 includes a pixel switch 2, a drive transistor 3, and a capacitor 4. The pixel switch 2 and the drive transistor 3 are switching elements formed, for example, by thin-film transistors.

In the pixel switch 2, a gate electrode is connected to a scanning line GL. One of a source electrode and a drain electrode of the pixel switch 2 is connected to a signal line SL, and the other is connected to the gate electrode of the drive transistor 3 and the capacitor 4. In the example shown in FIG. 1, the scanning line GL extends along the first direction X, and the signal line SL extends along the second direction Y. The signal line SL connects the pixel circuit 1 and the pad PD to each other. In the drive transistor 3, one of the source electrode and the drain electrode is connected to the power supply line PL and the capacitor 4, and the other is connected to the display element DE. Note that the configuration of the pixel circuit 1 is not limited to that of the example shown.

The display device DSP further comprise a dam ID surrounding the display area DA and a dam OD surrounding the display area DA and the dam ID. The dam ID and dam OD are each arranged in the peripheral area SA.

The dam ID includes an arc portion IDa and a straight portion IDb extending along the first direction X. The dam OD includes an arc portion ODa and a straight portion ODb extending along the first direction X. The centers of the arc portion IDa, arc portion ODa, display area DA, and main body portion 10a coincide with each other. Note that the centers of the arc portion IDa, arc portion ODa, display area DA, and main body portion 10a may not coincide with each other.

The straight portion IDb and straight portion ODb are located between the display area DA and the multiple pads PD. Note that the number of dams of the display device DSP is not limited to two, the dam ID and dam OD, but may as well be one, or three or more.

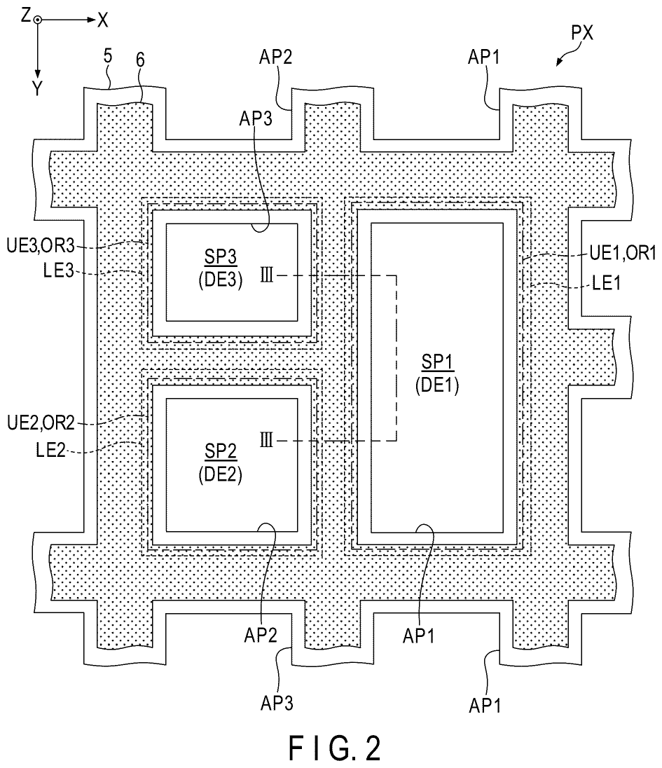

FIG. 2 is a plan view schematically showing an example of the layout of the subpixels SP1, SP2, and SP3. In the example shown in FIG. 2, the subpixels SP2 and SP3 are arranged along the subpixel SP1 in the first direction X. Further, the subpixels SP2 and SP3 are arranged along the second direction Y.

When the subpixels SP1, SP2, and SP3 are arranged in such a layout, a column in which the subpixels SP2 and SP3 are alternately arranged along the second direction Y, and a column in which multiple subpixels SP1 are repeatedly arranged along the second direction Y are formed in the display area DA. These columns are arranged alternately along the first direction X. Note that the layout of the subpixels SP1, SP2, and SP3 is not limited to that of the example shown in FIG. 2.

In the display area DA, a rib layer 5 is disposed. In this embodiment, the rib layer 5 corresponds to the second inorganic insulating layer. The rib layer 5 has pixel apertures AP1, AP2, and AP3 in the subpixels SP1, SP2, and SP3, respectively. In the example shown in FIG. 2, the pixel aperture AP1 is larger than the pixel aperture AP2, and the pixel aperture AP2 is larger than the pixel aperture AP3.

That is, among the subpixels SP1, SP2, and SP3, the aperture ratio of the subpixel SP1 is the largest, and the aperture ratio of the subpixel SP3 is the smallest. Note that the sizes of the pixel apertures AP1, AP2, and AP3 are not limited to those of this example. For example, at least two of the pixel apertures AP1, AP2, and AP3 may have the same size.

The subpixel SP1 comprises a lower electrode LE1, an upper electrode UE1, and an organic layer OR1, each overlapping the pixel aperture AP1. The subpixel SP2 comprises a lower electrode LE2, an upper electrode UE2, and an organic layer OR2, each overlapping the pixel aperture AP2. The subpixel SP3 includes a lower electrode LE3, an upper electrode UE3, and an organic layer OR3, each overlapping the pixel aperture AP3.

The portions of the lower electrode LE1, upper electrode UE1, and organic layer OR1, which overlap the pixel aperture AP1 constitute a display element DE1 of the subpixel SP1. The portions of the lower electrode LE2, upper electrode UE2, and organic layer OR2, which overlap the pixel aperture AP2 constitute a display element DE2 of the subpixel SP2. The portions of the lower electrode LE3, upper electrode UE3, and organic layer OR3, which overlap the pixel aperture AP3 constitute a display element DE3 of the subpixel SP3. The display elements DE1, DE2, and DE3 may further include a cap layer, which will be described later. The rib layer 5 surrounds each of the display elements DE1, DE2, and DE3.

In the display area DA, a partition 6 is disposed. The partition 6 is located above the rib layer 5 and entirely overlaps the rib layer 5. In the example shown in FIG. 2, the partition 6 has a planar shape similar to that of the rib layer 5. That is, the partition 6 has apertures in locations corresponding to the subpixels SP1, SP2, and SP3, respectively.

From another perspective, the rib layer 5 and partition 6 have a grid pattern in plan view, enclosing each of the display elements DE1, DE2, and DE3. The partition 6 encloses the pixel apertures AP1, AP2, and AP3. The partition 6 serves as wiring for supplying a common voltage to the upper electrodes UE1, UE2, and UE3.

The lower electrodes LE1, LE2, and LE3 are connected to the pixel circuits 1 (more specifically, the drain electrodes of the drive transistors 3 shown in FIG. 1) of the subpixels SP1, SP2, and SP3, respectively, through contact holes not shown. The contact holes not shown all overlap the rib layer 5 and the partition 6.

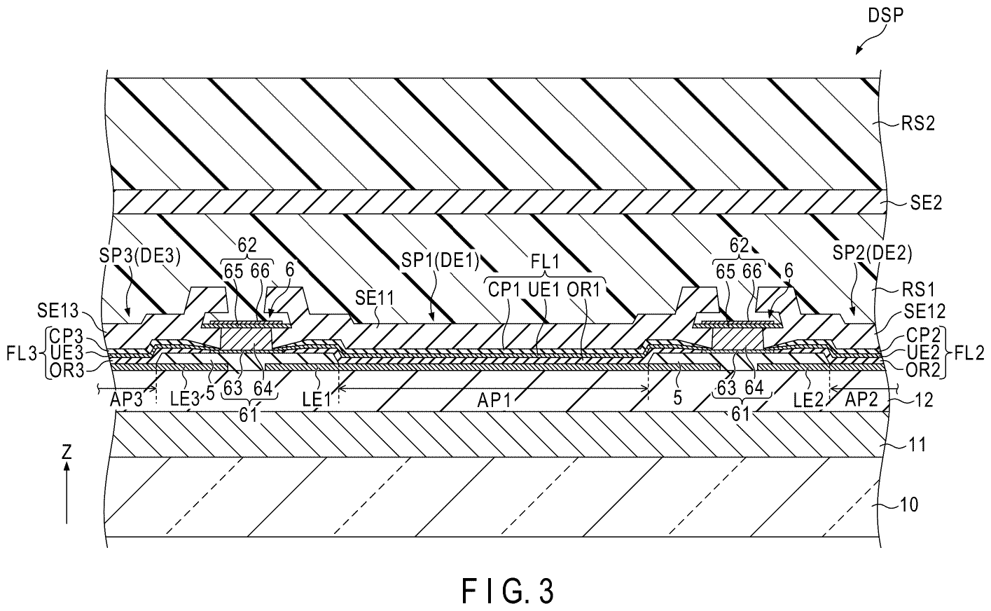

FIG. 3 is a cross-sectional view schematically showing the display device DSP taken along the line III-III in FIG. 2. The circuit layer 11 is disposed on the substrate 10 described above. The circuit layer 11 includes various circuits and wiring lines such as the pixel circuits 1, scanning lines GL, signal lines SL, and power supply lines PL shown in FIG. 1. The circuit layer 11 is covered by an organic insulating layer 12. The organic insulating layer 12 functions as a planarization film to planarize the unevenness caused by the circuit layer 11.

The lower electrodes LE1, LE2, and LE3 are each disposed on the organic insulating layer 12. The rib layer 5 is disposed on the organic insulating layer 12 and the lower electrodes LE1, LE2, and LE3. The end portions of the lower electrodes LE1, LE2, and LE3 are all covered by the rib layer 5.

The partition 6 includes a conductive lower portion 61 disposed on the rib layer 5 and an upper portion 62 disposed on the lower portion 61. The upper portion 62 has a width greater than that of the lower portion 61. With this configuration, both end portions of the upper portion 62 protrude beyond the side surfaces of the lower portion 61. That is, the partition 6 has an overhanging shape in which both end portions of the upper portion 62 protrude beyond the side surfaces of the lower portion 61.

In the example shown in FIG. 3, the lower portion 61 has a bottom layer 63 and an axis layer 64. The bottom layer 63 is located between the axis layer 64 and the rib layer 5. Further, in the example shown in FIG. 3, the upper portion 62 has a first top layer 65 and a second top layer 66. The first top layer 65 is disposed on the axis layer 64. The second top layer 66 is disposed on the first top layer 65.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the lower portion 61 of the partition 6.

The display element DE1 includes a cap layer CP1 that covers the upper electrode UE1. The display element DE2 includes a cap layer CP2 that covers the upper electrode UE2. The display element DE3 includes a cap layer CP3 that covers the upper electrode UE3. The cap layers CP1, CP2, and CP3 serve as optical adjustment layers to improve the light extraction efficiency of the light emitted from the organic layers OR1, OR2, and OR3, respectively.

In the following description, the stacked layer body constituted by the organic layer OR1, the upper electrode UE1, and the cap layer CP1 is referred to as a stacked layer film FL1, the stacked layer body constituted by the organic layer OR2, the upper electrode UE2, and the cap layer CP2 is referred to as a stacked layer film FL2, and the stacked layer body constituted by the organic layer OR3, the upper electrode UE3, and the cap layer CP3 is referred to as a stacked layer film FL3.

In the subpixels SP1, SP2, and SP3, sealing layers SE11, SE12, and SE13 are disposed to cover the stacked layer films FL1, FL2, and FL3, respectively. Specifically, the sealing layer SE11 continuously covers the partition 6 surrounding the cap layer CP1 and the subpixels SP1. The sealing layer SE12 continuously covers the partition 6 surrounding the cap layer CP2 and the subpixels SP2. The sealing layer SE13 continuously covers the partition 6 surrounding the cap layer CP3 and the subpixels SP3. That is, the sealing layers SE11, SE12, and SE13 are disposed above the upper electrodes UE1, UE2, UE3, and the partition 6.

In the example shown in FIG. 3, the sealing layer SE11 on the partition 6 between the subpixels SP1 and SP2 is spaced apart from the sealing layer SE12 on the partition 6. Further, the sealing layer SE11 on the partition 6 between the subpixels SP1 and SP3 is spaced apart from the sealing layer SE13 on the partition 6. Note here that any two of the sealing layers SE11, SE12, and SE13 may come into contact with each other above the partition 6.

For example, between the sealing layers SE11, SE12, and SE13 and the upper portion 62 of the partition 6, gaps are formed. At least portions of these gaps may be filled with the stacked layer films FL1, FL2, and FL3, respectively.

Furthermore, a resin layer RS1 is disposed to cover the sealing layers SE11, SE12, and SE13, a sealing layer SE2 is disposed to cover the resin layer RS1, and a resin layer RS2 is disposed to cover the sealing layer SE2. In this embodiment, the resin layer RS1 corresponds to the first resin layer, and the resin layer RS2 corresponds to the second resin layer. The resin layers RS1, RS2, and the sealing layer SE2 are continuously provided over the entire display area DA and a portion thereof extends over to the peripheral area SA.

A cover member such as a polarizer, protective film, or cover glass may be further disposed above the resin layer RS2. Such a cover member may be adhered to the resin layer RS2 via an adhesive layer such as an optical clear adhesive (OCA). Further, above the display elements DE1, DE2, and DE3, color filters corresponding to the colors of the subpixels SP1, SP2, and SP3 may be provided, respectively.

The organic insulating layer 12 is formed from an organic insulating material such as polyimide. The rib layer 5 and the sealing layers SE11, SE12, SE13, and SE2 are formed, for example, from inorganic insulating materials such as silicon nitride (SiNx), silicon oxide (SiOx), and silicon oxynitride (SiON).

In one example, the rib layer 5 is formed of silicon nitride, and the sealing layers SE11, SE12, SE13, and SE2 are formed of silicon nitride. The resin layers RS1 and RS2 are formed of a resin material (organic insulating material) such as epoxy resin or acrylic resin.

The lower electrodes LE1, LE2, and LE3 are each a stacked layer body containing a transparent electrode formed from an oxide conductive material such as ITO and a metal electrode formed from a metal material such as silver. The upper electrodes UE1, UE2, and UE3 are formed from a metal material such as a magnesium-silver alloy (MgAg). For example, the lower electrodes LE1, LE2, and LE3 correspond to the anodes, and the upper electrodes UE1, UE2, and UE3 correspond to the cathodes.

The organic layers OR1, OR2, and OR3 are constituted by multiple thin films including a light-emitting layer. For example, the organic layers OR1, OR2, and OR3 have a structure in which a hole injection layer, a hole transport layer, an electron blocking layer, an emissive layer, a hole blocking layer, an electron transport layer, and an electron injection layer are sequentially stacked along the third direction Z. Note here that the organic layers OR1, OR2, and OR3 may as well have some other structure, such as the so-called tandem structure including multiple light-emitting layers.

The cap layers CP1, CP2, and CP3 have, for example, a stacked layer structure in which multiple transparent layers are stacked one on another. These transparent layers may include a layer formed from an inorganic material and a layer formed from an organic material. Further, these transparent layers have different refractive indices. For example, the refractive indices of these transparent layers are different from the refractive indices of the upper electrodes UE1, UE2, UE3 and those of the sealing layers SE11, SE12, SE13. Note that at least one of the cap layers CP1, CP2, CP3 may be omitted.

To the partition 6, a common voltage is supplied. This common voltage is supplied to each of the upper electrodes UE1, UE2, and UE3, which are in contact with the lower portion 61. To the lower electrodes LE1, LE2, and LE3, pixel currents corresponding to the video signals of the signal lines SL are supplied through the pixel circuits 1 of the subpixels SP1, SP2, and SP3, respectively.

The organic layers OR1, OR2, and OR3 emit light according to the flowing current. Specifically, when current flows between the lower electrode LE1 and the upper electrode UE1, the light-emitting layer of the organic layer OR1 emits light in a blue wavelength band. When current flows between the lower electrode LE2 and the upper electrode UE2, the light-emitting layer of the organic layer OR2 emits light in a green wavelength band. When current flows between the lower electrode LE3 and the upper electrode UE3, the light-emitting layer of the organic layer OR3 emits light in a red wavelength band.

As another example, the light-emitting layers of the organic layers OR1, OR2, and OR3 may emit light of the same color (for example, white). In this case, the display device DSP may comprise color filters that convert the light emitted by the light-emitting layers into light of colors corresponding to the subpixels SP1, SP2, and SP3. Further, the display device DSP may as well comprise a layer containing quantum dots that generate light of colors corresponding to the subpixels SP1, SP2, and SP3 when excited by the light emitted by the light-emitting layers.

The bottom layer 63 and the axis layer 64 are formed, for example, from a metal material. As the metal material for the bottom layer 63, for example, molybdenum (Mo), titanium (Ti), titanium nitride (TiN), molybdenum-tungsten alloy (MoW), or molybdenum-niobium alloy (MoNb) may be used. As the metal material for the axis layer 64, for example, aluminum (Al), aluminum-neodymium alloy (AlNd), aluminum-yttrium alloy (AlY), or aluminum-silicon alloy (AlSi) may be used.

Note here that at least one of the bottom layer 63 and the axis layer 64 may have a stacked layer structure containing multiple layers. Additionally, the axial layer 64 may include a layer formed from an insulating material. Furthermore, it may have a single-layer structure in which the lower portion 61 is formed from a conductive material.

For example, the first top layer 65 is formed from a metal material, and the second top layer 66 is formed from a transparent conductive oxide. As the metal material of the first top layer 65, for example, titanium, titanium nitride, molybdenum, tungsten, molybdenum-tungsten alloy, or molybdenum-niobium alloy may be used. As the conductive oxide of the second top layer 66, for example, indium tin oxide (ITO), indium zinc oxide (IZO), or indium gallium zinc oxide (IGZO) can be used. Note that the upper portion 62 may have a single-layer structure formed from a specific material. Furthermore, the upper portion 62 may include a layer formed from an insulating material.

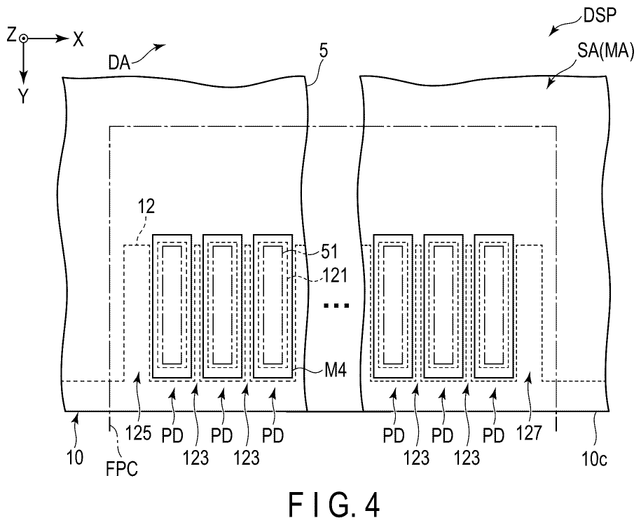

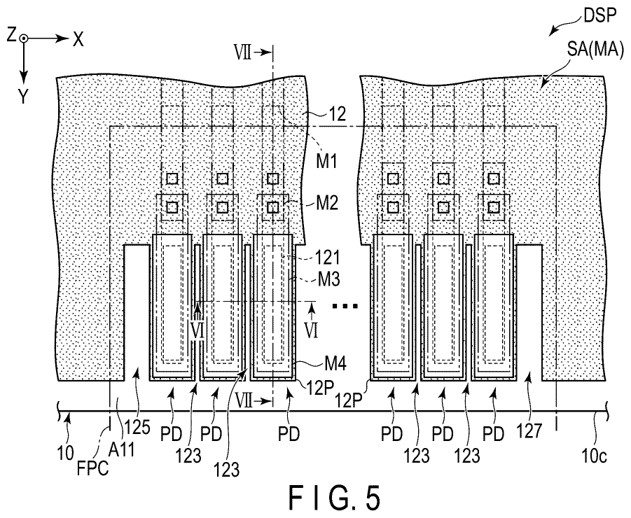

FIGS. 4 and 5 are plan views each showing a configuration example of a mount area MA of the display device DSP shown in FIG. 1. FIGS. 4 and 5 illustrates the vicinity of the substrate end 10c. The multiple pads PD are arranged along the first direction X and each extend along the second direction Y.

In FIGS. 4 and 5, the display area DA is formed in the upper portion of the figures. In FIGS. 4 and 5, the flexible printed circuit board FPC shown in FIG. 1 is indicated by an alternate long and short dash line. In FIG. 5, the rib layer 5 shown in the configuration example of FIG. 4 is omitted. In FIG. 5, dots are marked on the organic insulating layer 12.

The rib layer 5 and the organic insulating layer 12 are arranged not only in the display area DA but also in the mount area MA (peripheral area SA) as shown in FIGS. 4 and 5. The rib layer 5 is formed up to the substrate end 10c as shown in FIG. 4. In contrast, the organic insulating layer 12 is not formed up to the substrate end 10c, as shown in FIG. 5. In other words, the peripheral area SA has an area A11 at the substrate end 10c, where the organic insulating layer 12 is not formed.

The organic insulating layer 12 has a plurality of protruding portions 12P that overlap the pads PD, respectively. The protruding portions 12P have a shape that protrudes toward the substrate end 10c. As shown in FIG. 5, the organic insulating layer 12 has apertures 121 (first apertures) that overlap the pads PD, respectively, at the protruding portions 12P. The rib layer 5 has apertures 51 (second apertures) that overlap the pads PD, respectively, as shown in FIG. 4. The apertures 51 of the rib layer 5 overlap the apertures 121 of the organic insulating layer 12, respectively. In the example shown in FIG. 4, the aperture 51 and the aperture 121 overlap each pad PD.

The apertures 51 of the rib layer 5 and the apertures 121 of the organic insulating layer 12 extend in a direction different from the direction in which the pads PD are arranged. The apertures 51 and apertures 121 extend, for example, along the second direction Y. Specifically, the apertures 51 and apertures 121 have a rectangular shape that is elongated along the second direction Y.

In the example shown in FIG. 4, the area of the apertures 121 is greater than the area of the apertures 51 in plan view. The edge of each aperture 121 is located on an outer side of the edge of the respective aperture 51. With this configuration, the organic insulating layer 12 is not exposed from the apertures 51.

The organic insulating layer 12 further has slits 123 as shown in FIG. 5. The slits 123 are each formed between each respective adjacent pair of pads PD (protruding portions 12P). The multiple slits 123 extend along the second direction Y and are aligned along the first direction X. The slits 123 are opened toward the substrate end 10c. In other words, the slits 123 are connected to the area A11 of the substrate end 10c.

The organic insulating layer 12, as shown in FIG. 5, further includes slits 125 and 127 in the mount area MA. The multiple pads PD are located between the slit 125 and slit 127. The slits 125 and 127 are connected to the area A11 of the substrate end 10c. The rib layer 5 overlaps the slits 123, 125, 127, and the area A11 in plan view.

The display device DSP further comprises multiple metal layers M1, M2, M3, and M4 as shown in FIG. 5. Each of the metal layers M1, M2, M3, and M4 extends along the second direction Y. The metal layers M1, M2, M3, and M4 adjacent to each other are aligned at intervals along the first direction X. The pads PD are each constituted by the metal layers M3 and M4.

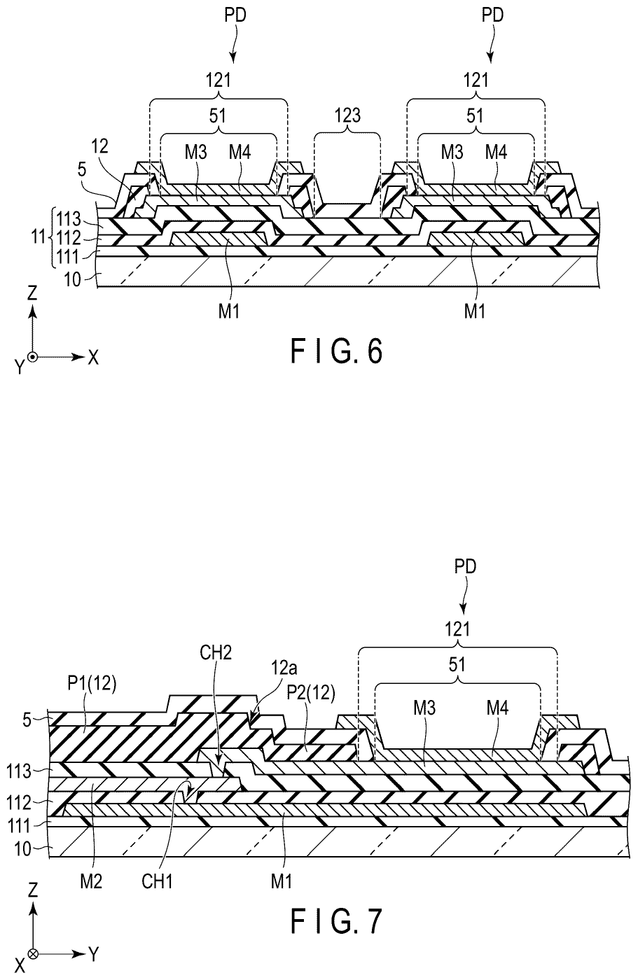

FIG. 6 is a cross-sectional view schematically showing the display device DSP taken along the line VI-VI in FIG. 5. FIG. 7 is a cross-sectional view schematically showing the display device DSP taken along the line VII-VII in FIG. 5.

As described above, the display device DSP comprises a circuit layer 11. The circuit layer 11 is disposed above the substrate 10, over the display area DA and the peripheral area SA (mount area MA). The circuit layer 11 includes inorganic insulating layers 111, 112, and 113. In this embodiment, the inorganic insulating layer 113 corresponds to the first inorganic insulating layer. The metal layers M1 and M2, together with the inorganic insulating layers 111, 112, and 113, constitute the circuit layer 11.

The inorganic insulating layer 111 is disposed on the substrate 10. The metal layer M1 is disposed on the inorganic insulating layer 111. The metal layer M1 is formed, for example, in the same layer as that of the scanning lines GL. The inorganic insulating layer 112 is disposed on the inorganic insulating layer 111 and the metal layer M1. The inorganic insulating layer 112 has a contact hole CH1 that overlaps the metal layer M1, as shown in FIG. 7.

The metal layer M2 is disposed on the inorganic insulating layer 112, as shown in FIG. 7. The metal layer M2 is formed, for example, in the same layer as that of the signal lines SL. The metal layer M2 extends toward the display area DA. The metal layer M2 is electrically connected to the metal layer M1 via the contact holes CH1. The inorganic insulating layer 113 is disposed on the inorganic insulating layer 112 and the metal layer M2. The inorganic insulating layer 113 has a contact hole CH2 that overlaps the metal layer M2.

The metal layer M3 is located directly above the metal layer M1 in the peripheral area SA and is disposed on the inorganic insulating layer 113. The metal layer M3 is electrically connected to the metal layer M2 via the contact hole CH2.

The organic insulating layer 12 is disposed on the inorganic insulating layer 113 and the metal layer M3. The organic insulating layer 12, as shown in FIGS. 6 and 7, covers the entire circumference of the peripheral portion of the metal layer M3.

The organic insulating layer 12 has multiple portions having different thicknesses. As shown in FIG. 7, the organic insulating layer 12 has a first portion P1 and a second portion P2 connected to the first portion P1. The aperture 121 is included in the second portion P2.

The second portion P2 has a thickness less than that of the first portion P1. Here, the thickness of the first portion P1 corresponds to the distance from the upper surface of the inorganic insulating layer 113 along the third direction Z, and the thickness of the second portion P2 corresponds to the distance from the upper surface of the metal layer M3 along the third direction Z.

In the example shown in FIG. 7, the metal layer M2 is disposed below the first portion P1, and the metal layer M2 is not disposed below the second portion P2. The first portion P1 and the second portion P2 form a step portion 12a in the organic insulating layer 12. For example, the portion of the organic insulating layer 12 on a side of the pad PD with relative to the step portion 12a corresponds to the second portion P2. Note that the second portion P2 may have a thickness equivalent to that of the first portion P1.

The rib layer 5 is disposed on the organic insulating layer 12 and the inorganic insulating layer 113. In other words, the rib layer 5 covers the organic insulating layer 12 and the inorganic insulating layer 113. The inorganic insulating layer 113 is exposed from the organic insulating layer 12 in the space between each adjacent pair of pads PD (slits 123), as shown in FIG. 6.

With this configuration, the rib layer 5 is in contact with the inorganic insulating layer 113 between each adjacent pair of pads PD. In other words, the inorganic insulating layer 113 is covered by the rib layer 5 in the slits 123. The metal layer M3 is exposed through the apertures 121 of the organic insulating layer 12 and the apertures 51 of the rib layer 5.

The metal layer M4 is disposed on the metal layer M3 and the rib layer 5. The pads PD are disposed above the inorganic insulating layer 113. The metal layer M4 is electrically connected to the metal layer M3 through the respective aperture 121 of the organic insulating layer 12 and the respective aperture 51 of the rib layer 5. The metal layer M4 overlaps the peripheral portion of the aperture 51 of the rib layer 5.

The inorganic insulating layers 111, 112, and 113 are formed from any one of silicon oxide, silicon nitride, and silicon oxynitride. The metal layers M2, M3, and M4 are each formed from multiple layers, for example.

In one example, the metal layers include two titanium layers formed from a titanium-based material and an aluminum layer formed from an aluminum-based material placed between the two titanium layers. Note that at least one of the metal layers M2, M3, and M4 may be formed by disposing an aluminum layer between layers formed from molybdenum-based materials.

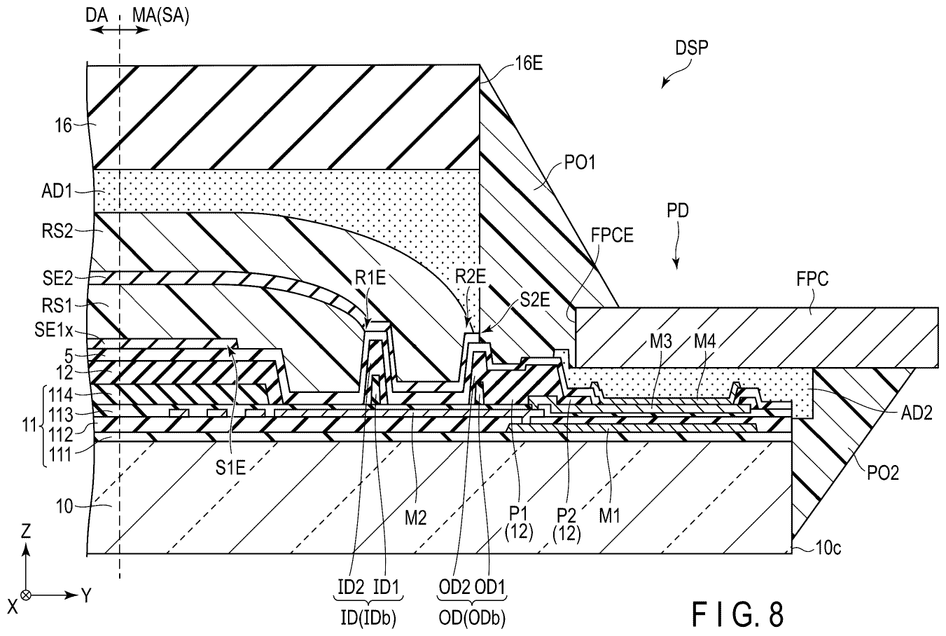

FIG. 8 is a cross-sectional view schematically showing the display device DSP taken along the line VIII-VIII in FIG. 1.

The circuit layer 11 further includes an organic insulating layer 114 formed from an organic insulating material. The organic insulating layer 114 is disposed on the inorganic insulating layer 113. The organic insulating layer 114 is covered by the organic insulating layer 12. Note that in the example shown in FIG. 8, the organic insulating layer 114 is located on an inner side of the dam ID.

On top of the rib layer 5, a sealing layer SE1x is disposed. The sealing layer SE1x is formed by the same process and the same material as those of any one of the sealing layers SE11, SE12, and SE13 shown in FIG. 3. In this embodiment, the sealing layers SE11, SE12, SE13, and SE1x correspond to the first sealing layer, and the sealing layer SE2 corresponds to the second sealing layer. Above the sealing layer SE1x, the resin layer RS1, sealing layer SE2, and resin layer RS2 as shown in FIG. 3 are disposed. The resin layer RS1 covers the sealing layers SE1x and the rib layer 5.

The display device DSP includes the dam ID and dam OD as described above. The dam ID and dam OD both protrude toward above the substrate 10. The dam ID and dam OD are disposed on the inorganic insulating layer 113. The dam ID and dam OD are covered by the rib layer 5.

The dam ID has the function of blocking the resin layer RS1. The dam ID includes a protrusion ID1 and a protrusion ID2. The protrusion ID2 covers the protrusion ID1. In the example shown in FIG. 8, the end portion RIE of the resin layer RS1 is located on a side of the dam ID. Note that the location of the end portion RIE is not limited to that of this example.

The dam OD has the function of blocking the resin layer RS2. The dam OD includes a protrusion OD1 and a protrusion OD2. The protrusion OD2 covers the protrusion OD1. In the example shown in FIG. 8, the end portion R2E of the resin layer RS2 is located directly above the dam OD. That is, the resin layer RS2 covers a part of the dam OD. Note that the location of the end portion R2E is not limited to that of this example.

Focusing on the organic insulating layer 12, the first portion P1 of the organic insulating layer 12 is connected to the protrusion OD2. In other words, the organic insulating layer 12 is continuously formed between the dam OD and the pads PD. That is, the organic insulating layer 12 is not disconnected between the dam OD and the pads PD. In the example shown in FIG. 8, the area including the portion of the organic insulating layer 12, that protrudes beyond the first portion P1 in the third direction Z, corresponds to the protrusion OD2 of the dam OD (straight portion ODb).

The protrusion ID1 and protrusion OD1 are formed from the same material and by the same manufacturing process as those of, for example, the organic insulating layer 114. The protruding portion ID2 and protruding portion OD2 are formed from the same material and by the same manufacturing process as those of, for example, the organic insulating layer 12. That is, in this embodiment, the dam ID and dam OD are formed from the same material as the organic insulating layers 114 and 12 and are formed in the same layers as the organic insulating layers 114 and 12, respectively.

The rib layer 5 covers the organic insulating layer 12, the dam ID, and the dam OD. The sealing layer SE2 overlaps each of the dam ID (straight portion IDb) and the dam OD (straight portion ODb). In contrast, the sealing layer SE1x does not overlap each of the dam ID (straight portion IDb) and the dam OD (straight portion ODb).

The display device DSP further comprises a polarizer 16 and protective members PO1 and PO2. The polarizer 16 is disposed above the sealing layer SE2. Specifically, the polarizer 16 is adhered to the resin layer RS2 by an adhesive AD1. The adhesive AD1 is formed, for example, from an optical clear adhesive (OCA).

The end portion 16E of the polarizer 16 is located directly above the dam OD in the example shown in FIG. 8. That is, the dam OD overlaps the end portion 16E of the polarizer 16 in plan view. Note that the dam OD may not overlap the end portion 16E in plan view.

The end portion SIE of the sealing layer SE1x is located on an inner side of the dam ID. The end portion S2E of the sealing layer SE2 is located on an outer side of the dam ID. In the example shown in FIG. 8, the end portion S2E of the sealing layer SE2 is located above the dam OD.

In the area on an outer side the dam ID, the sealing layer SE2 is in contact with the rib layer 5. In other words, the sealing layer SE2 and the rib layer 5 are in contact with each other between the display area DA and the dam OD. The resin layer RS1 is surrounded by the sealing layer SE1x, the rib layer 5, and the sealing layer SE2. With this configuration, it is possible to suppress moisture from penetrating into the resin layer RS1.

The flexible printed circuit board FPC is adhered to the metal layer M4 by an adhesive AD2. In the example shown in FIG. 8, the adhesive AD2 covers not only the metal layer M4 but also a part of the rib layer 5. As the adhesive AD2, a conductive material such as an anisotropic conductive film may be used. Additionally, the end portion FPCE of the flexible printed circuit board FPC overlaps the second portion P2 of the organic insulating layer 12. Here, the end portion includes the end itself and its vicinity area.

The protective member PO1 is disposed above the rib layer 5 between the polarizer 16 and the pads PD. The protective member PO1 is brought into contact with the end portion 16E of the polarizer 16 and covers the end portion FPCE of the flexible printed circuit board FPC. The protective member PO2 is brought into contact with the substrate 10, the circuit layer 11, the adhesive AD2, the flexible printed circuit board FPC, and other components.

The protective members PO1 and PO2 are formed from a resin material such as epoxy resin or acrylic resin. The protective member PO1 has the function of preventing moisture from entering the mount area MA between the end portion 16E of the polarizer 16 and the end portion FPCE of the flexible printed circuit board FPC, for example. The protective member PO2 has the function of preventing moisture from entering the mount area MA from the substrate end 10c of the substrate 10.

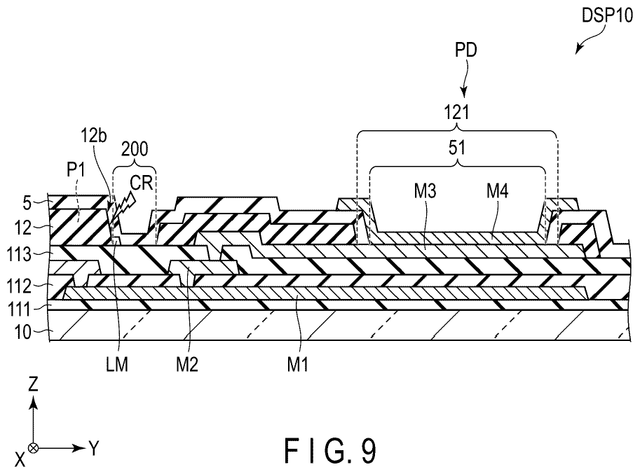

FIG. 9 is a cross-sectional view schematically showing a display device DSP10 according to a comparative example. The display device DSP10 according to the comparative example is different from the display device DSP according to the present embodiment in that the organic insulating layer 12 has a slit 200.

The slit 200 is located between the display area DA and the pads PD. The slit 200 is formed along the first direction X. The inorganic insulating layer 113 is exposed from the organic insulating layer 12 in the slit 200, as shown in FIG. 9. The rib layer 5 covers the inorganic insulating layer 113 in the slit 200.

Since the organic insulating layer 12 has the slit 200, a step portion 12b is formed in the organic insulating layer 12. The size of the step portion 12b along the third direction Z is greater than the size of the step portion 12a (shown in FIG. 7) along the third direction Z.

Due to the step portion 12b with such a configuration, the material for forming the lower electrode may remain in the slit 200 (residual portion LM shown in FIG. 9) or stress may concentrate on the rib layer 5 which overlaps the step portion 12b. Therefore, a crack (crack CR shown in FIG. 9) may be created in the rib layer 5.

The crack CR with such a configuration may serve as a pathway for moisture to enter. Entering of moisture from the residual portion LM and the crack CR in the slit 200 may cause corrosion of wiring lines (for example, metal layers M2, M3, and the like). Such corrosion of the wiring lines may lead to a degradation in the reliability of the display device DSP.

In this embodiment, the organic insulating layer 12 is not disconnected between the dam OD and the first portion P1. Specifically, the organic insulating layer 12 is continuously formed between the dam OD and the pads PD.

In other words, the organic insulating layer 12 of the present embodiment is flatter in the first portion P1 than the organic insulating layer 12 of the display device DSP 10 of the comparative example, and no step portion 12b is formed. With this configuration, the generation of the residual portion LM (shown in FIG. 9) can be suppressed and the concentration of stress on the rib layer 5 can be prevented, thereby making it possible to suppress the occurrence of cracks. As a result, the wiring lines are less prone to corrosion, thereby suppressing a degradation in the reliability of the display device DSP.

Further, in this embodiment, the rib layer 5 formed from an inorganic insulating material is in contact with the inorganic insulating layer 113 through the slit 123 and is firmly attached thereto. With this configuration, the adhesion between the rib layer 5 and the substrate layer can be improved, thereby suppressing peeling-off of the rib layer 5.

Furthermore, in this embodiment, the organic insulating layer 12 has a first portion P1 and a second portion P2 having a thickness less than that of the first portion P1. The flexible printed circuit board FPC is disposed above the second portion P2.

With the above-described configuration, the step portion created between the flexible printed circuit board FPC and the first portion P1 of the organic insulating layer 12 can be minimized when the flexible printed circuit board FPC is placed. Additionally, in the area where the flexible printed circuit board FPC does not overlap, the thickness can be increased by the first portion P1, and therefore the elements located below the organic insulating layer 12 can be adequately protected.

As described above, according to the configuration of the present embodiment, it is possible to provide a display device DSP that can suppress a decrease in reliability. Various other advantageous effects can also be obtained from the present embodiment.

Next, other embodiments will be described. Note that in the other embodiments to be described below, for structural elements similar to those used in the first embodiment are denoted by the same reference numerals as those in the first embodiment, and their detailed descriptions may be omitted or simplified.

### Second Embodiment

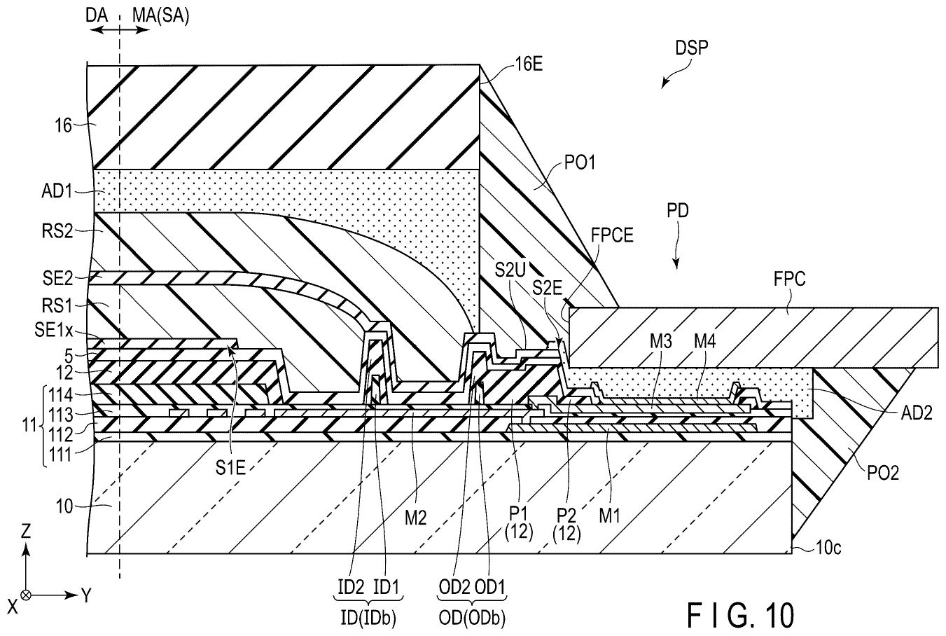

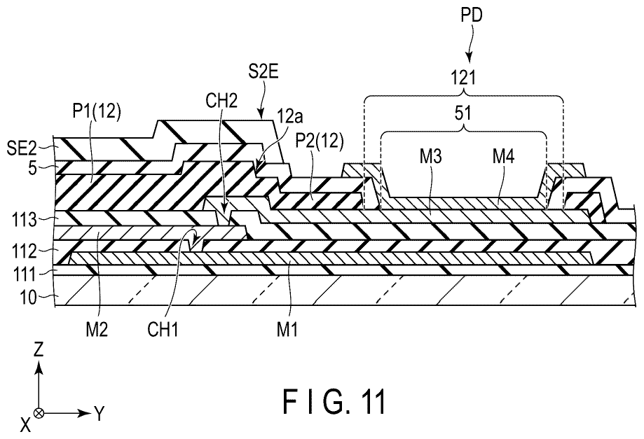

FIGS. 10 and 11 are each a cross-sectional view schematically showing a display device DSP according to this embodiment. FIG. 11 illustrates an enlarged view of the vicinity of the pad PD shown in FIG. 10. In FIG. 11, elements such as the flexible printed circuit board FPC, adhesive AD2, and protective members PO1 and PO2 are omitted in part.

In this embodiment, the sealing layer SE2 extends toward the pad PD more than that of the case in the first embodiment, as shown in FIGS. 10 and 11. Specifically, the end portion SE2E of the sealing layer SE2 is located on a side of the pad PD with relative to the end portion 16E of the polarizer 16.

The sealing layer SE2 extends to a location where it overlaps the step portion 12a of the organic insulating layer 12, for example, as shown in FIG. 11. From another perspective, the sealing layer SE2 overlaps the first portion P1 of the organic insulating layer 12. From yet another perspective, the sealing layer SE2 overlaps a part of the metal layer M3.

Focusing on the adhesive AD2, the adhesive AD2 covers not only the metal layer M4 but also the rib layer 5 and a part of the sealing layer SE2, as shown in FIG. 10. The protective member PO1 overlaps the end portion SE2E of the sealing layer SE2 and is brought into contact with the upper surface SE2U of the sealing layer SE2. In the mount area MA, the sealing layer SE2 is located between the rib layer 5 and the protective member PO1.

In this embodiment as well, advantageous effects similar to those of the first embodiment can be achieved. In this embodiment, the end portion S2E of the sealing layer SE2 is located on the side of the pad PD with relative to the end portion 16E of the polarizer 16. With this configuration, the rib layer 5 is covered by the sealing layer SE2, and therefore even if cracks occur in the rib layer 5, moisture is less likely to penetrate into the mount area MA, thereby making it possible to further suppress a decrease in reliability.

### Third Embodiment

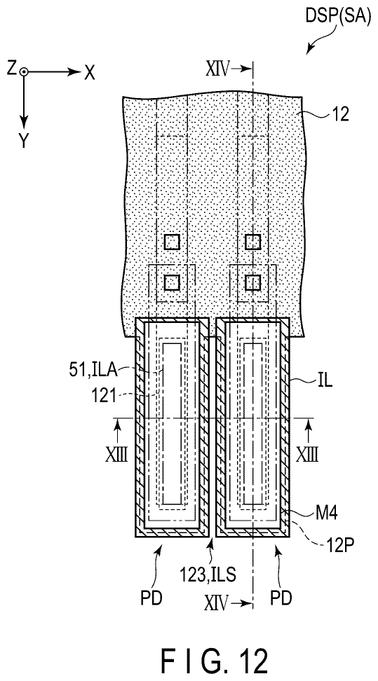

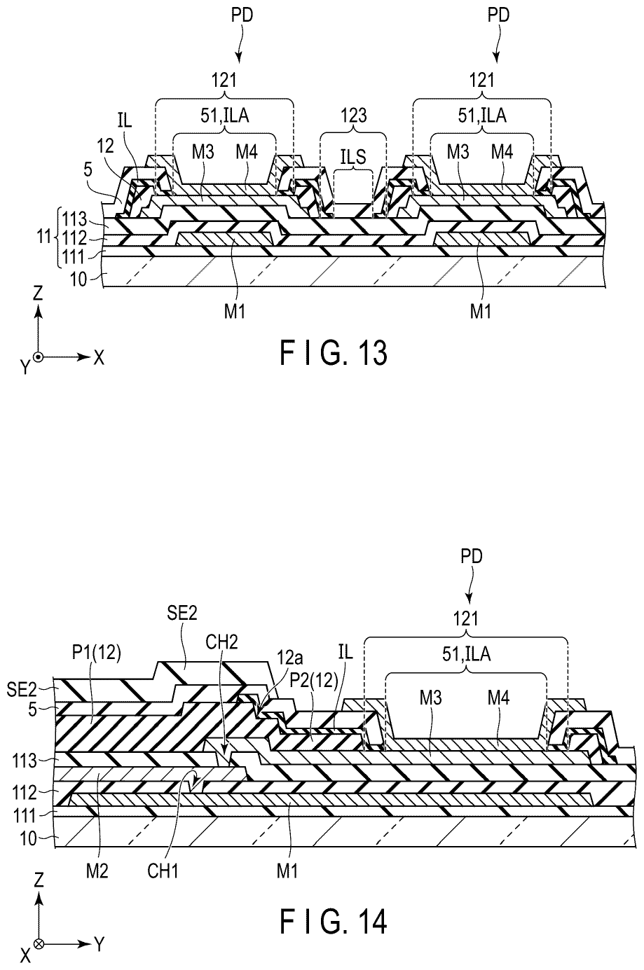

FIG. 12 is a plan view schematically showing a display device DSP according to this embodiment. FIG. 13 is a cross-sectional view schematically showing the display device DSP taken along the line XIII-XIII in FIG. 12. FIG. 14 is a cross-sectional view schematically showing the display device DSP taken along the line XIV-XIV in FIG. 12. This embodiment is different from the second embodiment in that it further includes an inorganic insulating layer IL. In FIG. 12, dots are marked on the organic insulating layer 12, and diagonal lines are marked on the inorganic insulating layer IL.

As shown in FIG. 12, multiple inorganic insulating layers IL are disposed in the peripheral area SA. Focusing on the peripheral area SA, there are multiple inorganic insulating layers IL formed to cover the multiple protruding portions 12P, respectively. The width of the inorganic insulating layers IL along the first direction X is greater than the width of the protruding portions 12P along the first direction X.

The multiple inorganic insulating layers IL each have an aperture ILA (third aperture) that overlap the respective one of the pads PD. The apertures ILA overlap the apertures 121 of the organic insulating layer 12 and the apertures 51 of the rib layer 5, respectively. The apertures 51 have a size equivalent to that of as the apertures ILA, for example, in plan view.

Each pair of inorganic insulating layers IL adjacent to each other along the first direction X are spaced apart between each respective adjacent pair of pads PD. In other words, a slit ILS are formed between each adjacent pair of inorganic insulating layers IL.

The inorganic insulating layers IL are disposed on the inorganic insulating layer 113, the metal layer M3, and the organic insulating layer 12, respectively, as shown in FIGS. 13 and 14. The respective inorganic insulating layer IL covers the organic insulating layer 12. Note that a part of the organic insulating layer 12 is exposed from the inorganic insulating layer IL.

The peripheral portion of the organic insulating layer 12 is not exposed from the inorganic insulating layer IL in the protruding portion 12P. From another perspective, as shown in FIG. 13, the inorganic insulating layer IL is brought into contacts the metal layer M3 in the aperture 121, and is brought into contact with the inorganic insulating layer 113 on an outer side of the aperture 121 (for example, between adjacent pads PD).

The slit ILS of the inorganic insulating layer IL overlaps the respective slit 123 of the organic insulating layer 12. The width of the slit ILS along the first direction X is less than the width of the slit 123 along the first direction X, for example. The inorganic insulating layer 113 is exposed from the inorganic insulating layer IL between each adjacent pair of pads PD (slits ILS), as shown in FIG. 13.

The rib layer 5 is disposed on the organic insulating layer 12 and the inorganic insulating layers 113 and IL. In other words, the inorganic insulating layer IL is disposed between the organic insulating layer 12 and the rib layer 5. The rib layer 5 has a thickness that is greater than that of the inorganic insulating layer IL, for example.

The rib layer 5 is brought into contact with the inorganic insulating layer 113 between each adjacent pair of pads PD. In other words, the inorganic insulating layer 113 is covered by the rib layer 5 in the slits ILS.

The metal layer M3 is exposed from the apertures 121 of the organic insulating layer 12, the apertures ILA of the inorganic insulating layer IL, and the apertures 51 of the rib layer 5. The metal layer M4 is electrically connected to the metal layer M3 through the apertures 121 of the organic insulating layer 12, the apertures 51 of the rib layer 5, and the apertures ILA of the inorganic insulating layer IL.

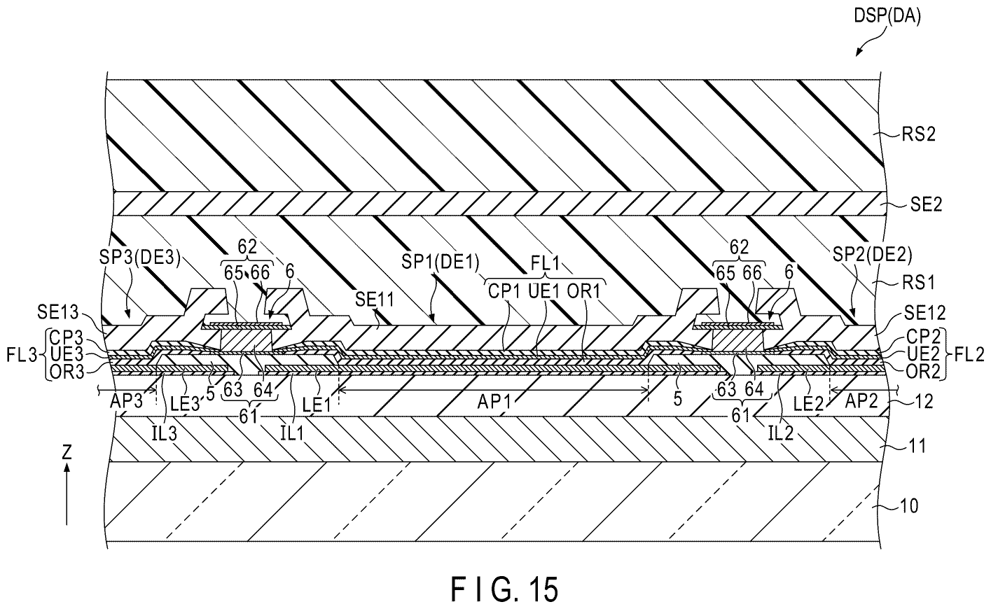

FIG. 15 is a cross-sectional view schematically showing the display device DSP according to this embodiment. Focusing on the display area DA, as shown in FIG. 15, the inorganic insulating layers IL1, IL2, and IL3 are disposed on the organic insulating layer 12. The inorganic insulating layers IL are formed using the same material and the same manufacturing process as those of the inorganic insulating layers IL1, IL2, and IL3, for example, in the display area DA.

The lower electrodes LE1, LE2, and LE3 are disposed on the inorganic insulating layers IL1, IL2, and IL3, respectively. That is, the inorganic insulating layers IL1, IL2, and IL3 are disposed between the organic insulating layer 12 and the lower electrodes LE1, LE2, and LE3 in the display area DA, respectively.

The inorganic insulating layers IL1, IL2, IL3, and IL are formed from an inorganic insulating material different from that of the rib layer 5, for example. In this embodiment, the inorganic insulating layers IL1, IL2, IL3, and IL correspond to the third inorganic insulating layers. In one example, the inorganic insulating layers IL1, IL2, IL3, and IL are formed of silicon nitride, and the rib layer 5 is formed of silicon nitride.

In this embodiment as well, advantageous effects similar to those of the second embodiment can be achieved. In this embodiment, since the organic insulating layer 12 is covered by the inorganic insulating layers IL, trimming of the organic insulating layer 12 during the manufacturing process can be suppressed. In other words, exposure of aluminum from the side walls of the metal layer M3 is less likely to occur.

As a result, during the processing steps of forming the lower electrodes LE1, LE2, and LE3, the precipitation of silver near the metal layer M3 can be suppressed, thereby making it possible to prevent the occurrence of electrical connection error between the metal layer M3 and the metal layer M4. Consequently, in this embodiment, the reliability of the display device DSP can be further suppressed from degrading.

Note that in this embodiment, such an example case is disclosed that each pair of inorganic insulating layers IL adjacent to each other along the first direction X are spaced apart, but the inorganic insulating layers IL adjacent to each other need not be spaced apart. In this case, the rib layer 5 formed of an inorganic insulating material is brought into contact with the inorganic insulating layer IL between each adjacent pair of pads PD.

Based on the display devices described above as embodiments of the invention, a person having ordinary skill in the art may achieve display device with arbitral design changes; however, as long as they fall within the scope and spirit of the present invention, all of such display devices are encompassed by the scope of the present invention. A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the present embodiments, any advantage and effect those will be obvious from the description of the specification or arbitrarily conceived by a skilled person are naturally considered achievable by the present invention.

What is claimed is:

1. A display device comprising:
a substrate;
a first inorganic insulating layer disposed above the substrate over a display area which displays images and a peripheral area surrounding the display area;
pads disposed above the first inorganic insulating layer in the peripheral area;
a dam disposed above the first inorganic insulating layer and surrounding the display area; and
an organic insulating layer continuously formed between the dam and the pads to connect to the dam, and including a first aperture overlapping each respective one of the pads.

2. The display device of claim 1, further comprising:
a second inorganic insulating layer covering the organic insulating layer and the dam and having a second aperture overlapping the first aperture.

3. The display device of claim 2, further comprising:
a lower electrode disposed above the organic insulating layer in the display area,
wherein
the second inorganic insulating layer includes a pixel aperture overlapping the lower electrode in the display area.

4. The display device of claim 3, further comprising:
an organic layer covering the lower electrode through the pixel aperture and emitting light according to current flowing thereto, and
an upper electrode covering the organic layer.

5. The display device of claim 4, further comprising:
a partition surrounding the pixel aperture in the display area,
wherein
the partition includes a lower portion disposed above the second inorganic insulating layer and an upper portion having an end portion protruding from side surfaces of the lower portion.

6. The display device of claim 5, further comprising:
a first sealing layer formed of an inorganic material and disposed above the upper electrode and the partition in the display area;
a first resin layer covering the first sealing layer; and
a second sealing layer covering the first resin layer and formed of an inorganic material,
wherein
the second sealing layer is brought into contact with the second inorganic insulating layer between the dam and the display area.

7. The display device of claim 6, further comprising:
a second resin layer covering the second sealing layer,
wherein an end portion of the second resin layer is located above the dam.

8. The display device of claim 7, further comprising:
a polarizer disposed above the second sealing layer,
wherein
an end portion of the second sealing layer is located on a side of a respective one of the pads with relative to an end portion of the polarizer.

9. The display device of claim 7, further comprising:
a polarizer disposed above the second sealing layer; and
a protective member brought into contact with the end portion of the polarizer and disposed above the second inorganic insulating layer.

10. The display device of claim 9, further comprising:
a flexible substrate connected to the pads,
wherein
the protective member covers an end portion of the flexible substrate.

11. The display device of claim 10, wherein
an end portion of the second sealing layer is located on a side of a respective one of the pads with relative to the end portion of the polarizer.

12. The display device of claim 11, wherein
the protective member overlaps the end portion of the second sealing layer.

13. The display device of claim 1, further comprising:
a flexible substrate connected to the pad,
wherein
the organic insulating layer includes a first portion connected to the dam, and a second portion connected to the first portion and including the first aperture,
the second portion has a thickness less than that of the first portion, and
the flexible substrate overlaps the second portion.

14. The display device of claim 2, wherein
the organic insulating layer has a slit formed between each adjacent pair of the pads.

15. The display device of claim 14, wherein
the second inorganic insulating layer is in contact with the first inorganic insulating layer between each adjacent pair of the pads.

16. The display device of claim 3, further comprising:
a third inorganic insulating layer,
wherein
the third inorganic insulating layer, in the display area, is disposed between the organic insulating layer and the lower electrode, and
the third inorganic insulating layer, in the peripheral area, covers the organic insulating layer and includes a third aperture overlapping the first aperture.

17. The display device of claim 16, wherein
the third inorganic insulating layer is in contact with the first inorganic insulating layer between each adjacent pair of the pads.

18. The display device of claim 16, wherein
the third inorganic insulating layer is formed of an inorganic insulating material different from that of the second inorganic insulating layer.
